(19) United States
(12) Patent Application Publication
(10) Pub. No.: US 2018/0283912 A1
(43) Pub. Date: Oct. 4, 2018

(54) SIGNAL PROCESSING DEVICE, DETECTION DEVICE, PHYSICAL QUANTITY MEASUREMENT DEVICE, ELECTRONIC APPARATUS, AND VEHICLE

(71) Applicant: Seiko Epson Corporation, Tokyo (JP)

(72) Inventor: Hideo HANEDA, Matsumoto (JP)

(21) Appl. No.: 15/926,317

(22) Filed: Mar. 20, 2018

(30) Foreign Application Priority Data
Mar. 28, 2017 (JP) 2017-062057

(51) Int. Cl. G01D 18/00; G01C 19/5776; H03H 17/02; G01D 15/24

(52) U.S. Cl. CPC G01D 18/006; G01C 19/5776; H03H 2017/0205; G01D 15/24; H03H 17/0202

(57) ABSTRACT

A signal processing device includes a Kalman filter that performs Kalman filter processing based on an observation noise and a system noise and outputs a DC component of an input signal as an estimated value; and a monitoring circuit. The Kalman filter outputs an error covariance of the estimated value. The monitoring circuit performs a stop command of observation update processing in the Kalman filter, based on a result of determination processing based on the error covariance, with respect to a signal level corresponding to the input signal.

### BACKGROUND

### 1. Technical Field

The present invention relates to a signal processing device, a detection device, a physical quantity measurement device, an electronic apparatus, and a vehicle.

### 2. Related Art

A physical quantity measurement device for detecting a physical quantity changing due to an external factor is incorporated into an electronic apparatus such as a digital camera and a smartphone, or a vehicle such as a vehicle and an airplane. For example, a gyro sensor detecting angular velocity is used for a so-called camera shake correction, a posture control, a GPS autonomous navigation, and the like.

In the physical quantity measurement device, if DC offset is included in a detection signal from a physical quantity transducer, there is a possibility of causing an error when the physical quantity from the detection signal is obtained. For example, a gyro sensor integrates angular velocity to calculate an angle, and thus, if DC offset (error of zero point) is included in the angular velocity, there is a concern that an error of the angle increases.

JP-A-2015-114220 discloses a technique of extracting a DC component of an input signal by using Kalman filter processing and subtracting the DC component from the input signal, as a technique of reducing the DC offset. In the technique, a signal processing device includes an input signal monitoring circuit that monitors the input signal and a Kalman filter that performs the Kalman filter processing and extracts the DC component of the input signal. The input signal monitoring circuit determines whether or not a signal level of the input signal exceeds a predetermined range, and the Kalman filter stops time update of an error covariance in a case where it is determined that the signal level exceeds the predetermined range.

In the above-described technique of the related art, in a case where the signal level of the input signal exceeds the predetermined range, the Kalman filter stops the time update of the error covariance. That is, threshold value setting for switching between validity and invalidity of an estimation operation of the Kalman filter is fixed. Accordingly, there is a concern that, in a case where there is an input (for example, rotation of very small angular velocity in the gyro sensor) smaller than a fixed threshold value, the estimation operation of the Kalman filter does not stop and an estimated value follows the input. By doing so, there is a concern that accuracy or stability of the estimated value on a true value of the DC component is reduced.

### SUMMARY

An advantage of some aspects of the invention is to solve at least a part of the problems described above, and the invention can be implemented as the following forms or embodiments.

An aspect of the invention relates to a signal processing device including a Kalman filter that performs Kalman filter processing based on an observation noise and a system noise and outputs a DC component of an input signal as an estimated value; and a monitoring circuit, in which the Kalman filter outputs an error covariance of the estimated value, and in which the monitoring circuit performs a stop command of observation update processing in the Kalman filter, with respect to a signal level corresponding to the input signal, based on a result of determination processing based on the error covariance.

According to the aspect of the invention, determination processing for a signal level corresponding to an input signal is performed based on an error covariance, and a stop command of observation update processing performed by the Kalman filter is performed based on results of the determination processing. Thereby, it is possible to adaptively change the signal level for performing the stop command according to the error covariance. By adaptively changing the signal level for performing the stop command according to the error covariance, it is possible to improve accuracy or stability of an estimated value (DC component) estimated by the Kalman filter.

In the aspect of the invention, the monitoring circuit may perform the stop command in a case where the signal level exceeds a threshold value based on the error covariance.

According to this configuration, determination processing based on an error covariance can be realized by comparing a signal level corresponding to an input signal with a threshold value based on the error covariance. For example, as the error covariance converges, the threshold value decreases, and thus, it is possible to stop observation update processing of the Kalman filter only by a slight change in the input signal.

In the aspect of the invention, the stop command may be a command of update stop of at least one of the estimated value and the error covariance.

According to this configuration, at least a part of observation update performed by the Kalman filter stops based on results of determination processing based on an error covariance. In a case where an input signal that hinders estimation of DC offset is input, at least a part of the observation update stops, and thus, it is possible to improve accuracy or stability of an estimated value.

In the aspect of the invention, the monitoring circuit may perform the determination processing with respect to the signal level of a signal which is obtained by subtracting the estimated value from the input signal.

Since DC offset is included in an input signal, a signal level thereof becomes a level including a magnitude of DC offset. In this regard, by subtracting an estimated value from the input signal, the signal level from which (estimated value of) the DC offset is removed is obtained. By performing determination processing on the signal level, more accurate determination processing can be performed.

In the aspect of the invention, the monitoring circuit may perform the determination processing with respect to the signal level of a signal which is obtained by performing square calculation processing of a signal corresponding to the input signal.

By performing square calculation processing of a signal corresponding to an input signal, a signal level representing (square of) a magnitude of the signal corresponding to the input signal can be generated. Thereby, a comparison between the signal level and a threshold value becomes a comparison between positive values, and whether or not the signal level exceeds the threshold value can be determined.

In the aspect of the invention, the monitoring circuit may include a gain processing circuit that performs gain processing of the error covariance, an offset addition processing circuit that performs offset addition processing to an output of the gain processing circuit, and a comparator that performs processing of comparing the signal level with an output of the offset addition processing circuit as the determination processing.

By performing gain processing of an error covariance and performing offset addition processing to the gain processing result, a threshold value that changes according to the error covariance can be obtained. By comparing a signal level corresponding to an input signal with an output of an offset addition processing circuit, determination processing on whether or not the signal level exceeds the threshold value that changes according to the error covariance can be performed.

In the aspect of the invention, the signal processing device may further include a noise estimation circuit that estimates the observation noise and the system noise which dynamically change according to the input signal.

According to the aspect of the invention, a noise estimation circuit dynamically changes an observation noise and a system noise in accordance with an input signal and supplies the observation noise and the system noise to a Kalman filter, and the Kalman filter receives the observation noise and the system noise which dynamically change and performs Kalman filter processing. As such, the observation noise and the system noise are supplied from the outside of the Kalman filter, and thus, it is possible to control a characteristic of the Kalman filter and to extract a DC component with improved transient response and followability.

Another aspect of the invention relates to a detection device including a drive circuit that drives a physical quantity transducer; a detection circuit that receives a detection signal from the physical quantity transducer and detects a physical quantity signal corresponding to a physical quantity; and the signal processing device described in any one of the above-described items, which extracts the DC component that is the estimated value by using the physical quantity signal as the input signal.

Still another aspect of the invention relates to a physical quantity measurement device including the detection device described in the aspect; and the physical quantity transducer.

Still another aspect of the invention relates to an electronic apparatus including the signal processing device described in any one of the aspects.

Still another aspect of the invention relates to a vehicle including the signal processing device described in any one of the aspects.

### BRIEF DESCRIPTION OF THE DRAWINGS

The invention will be described with reference to the accompanying drawings, wherein like numbers reference like elements.

FIG. 1 is a timing chart illustrating a comparative example of estimation processing of DC components performed by a Kalman filter.

FIG. 2 is a first configuration example of a signal processing device according to the present embodiment.

FIG. 3 is a first timing chart schematically illustrating an operation of the signal processing device according to the present embodiment.

FIG. 4 is a second timing chart illustrating the operation of the signal processing device according to the present embodiment.

FIG. 5 is a second configuration example of the signal processing device according to the present embodiment.

FIG. 6 is a detailed configuration example of the signal processing device according to the present embodiment.

FIG. 7 is a diagram illustrating a threshold value setting method.

FIG. 8 is a configuration example of a detection device.

FIG. 9 is a configuration example of a physical quantity measurement device.

FIG. 10 is a configuration example of a vehicle.

FIG. 11 is a configuration example of an electronic apparatus.

### DESCRIPTION OF EXEMPLARY EMBODIMENTS

Hereinafter, preferred embodiments according to the invention will be described in detail. The present embodiments which will be described below do not unduly limit contents of the invention described in the appended Claims, and all of the configurations described in the present embodiments are not necessarily indispensable as means for solving the invention.

For example, in the following description, a signal processing device according to the invention will be described by taking a case where DC offset (DC components) is extracted from a detection signal (physical quantity signal corresponding to angular velocity) of a gyro sensor. However, the invention is not limited to the detection signal of the gyro sensor, and can be applied to, for example, extracting DC offset of a physical quantity signal of another physical quantity transducer, or extracting DC offset from an input signal from not only the physical quantity transducer but also a certain circuit, a device, or the like.

### 1. Comparative Example

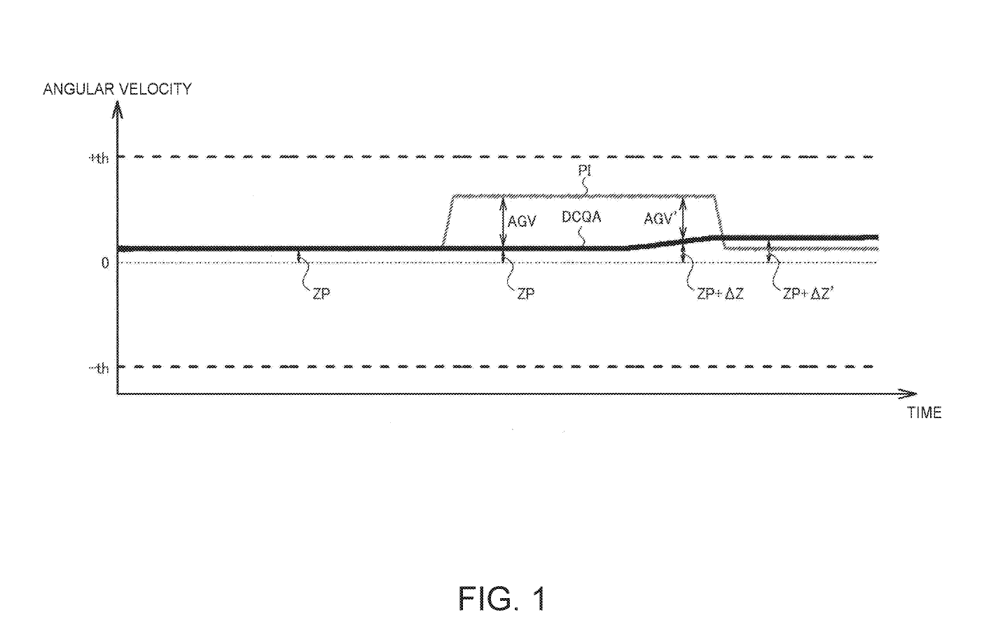

FIG. 1 is a timing chart illustrating a comparative example of estimation processing of DC components performed by the Kalman filter. A vertical axis is angular velocity (dps: degree per second) represented by a signal value.

An input signal PI to a Kalman filter includes DC offset corresponding to angular velocity ZP. The Kalman filter estimates (so-called zero point estimation) the DC offset from the input signal PI which is an observed value, and outputs DC component DCQA which is an estimated value. Since a value obtained by subtracting the DC offset from the observed value is true angular velocity, a detection value of the angular velocity is obtained by PI−DCQA. For example, in a case where a gyro sensor is stationary, PI=0+ZP. If a true value of the DC offset can be estimated by the Kalman filter, DCQA=ZP is obtained, and thereby, the detection value of the angular velocity becomes PI−DCQA=(0+ZP)−ZP=0 and correct angular velocity is detected.

In a case where the gyro sensor rotates, the input signal PI is the angular velocity which is not DC offset, and thus, it is desirable not to use the input signal PI for zero point estimation. Accordingly, in a case where an absolute value of the input signal PI exceeds a threshold value th, an estimation operation of the Kalman filter is temporarily stopped.

At this time, it is assumed that a very small rotation is input to the gyro sensor and the input signal becomes PI=AGV+ZP. If the input signal PI is |AGV+ZP|<th, the estimation operation of the Kalman filter does not stop, and thereby, the DC component DCQA is estimated based on the input signal PI=AGV+ZP. In this case, it is considered that the DC component DCQA gradually approaches AGV+ZP from ZP. Accordingly, the DC component DCQA includes an estimation error ΔZ with respect to the true value (ZP) of the DC offset, and DCQA=ZP+ΔZ. By doing so, the detection value of the angular velocity becomes AGV′=(AGV+ZP)−(ZP+ΔZ)=AGV−ΔZ, and is smaller than the true value (AGV) by the estimation error ΔZ of a zero point.

In addition, it is assumed that the DC component DCQA includes the estimation error ΔZ′, the gyro sensor is stationary in a state where DCQA=ZP+ΔZ′, and an input signal returns to PI=ZP. In this case, the detection value of the angular velocity is ZP−(ZP+ΔZ′)=−ΔZ′, and thereby, the angular velocity is detected regardless of the fact that the gyro sensor is actually stationary.

As described above, if the threshold value th for determining a rotation of the gyro sensor is fixed, there is a concern that a zero point estimation is inaccurate (or unstably changes with time). Since the zero point estimation is inaccurate, the detection value of the angular velocity may be inaccurate.

### 2. First Configuration Example of Signal Processing Device

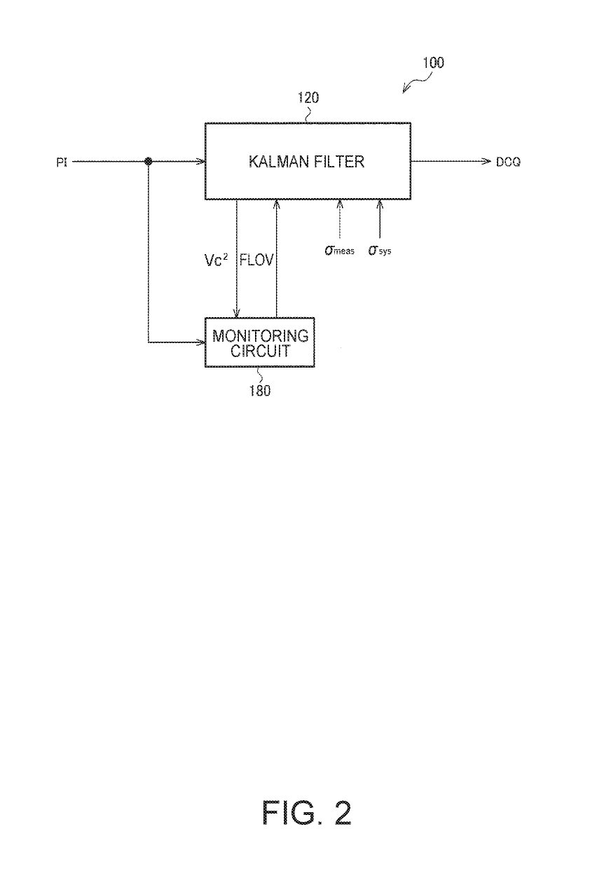

FIG. 2 illustrates a first configuration example of a signal processing device according to the present embodiment. The signal processing device 100 includes a Kalman filter 120 and a monitoring circuit 180. The present embodiment is not limited to the configuration of FIG. 2, and various modifications such as omitting a part of configuration elements and adding other configuration elements can be made.

The Kalman filter 120 performs Kalman filter processing based on an observation noise σₘₑₐₛ and a system noise σ_{sys}, and outputs the DC component DCQ of the input signal PI as an estimated value. In addition, the Kalman filter 120 outputs an error covariance Vc² of the estimated value. The monitoring circuit 180 performs a stop command of observation update processing in the Kalman filter 120, based on results of determination processing based on the error covariance Vc², with respect to a signal level corresponding to the input signal PI.

By doing so, it is possible to adaptively change the signal level for performing the stop command of an observation update processing, depending on the error covariance Vc². For example, it is possible to set a threshold value that changes depending on the error covariance Vc², not in a fixed threshold value as in the comparative example.

The error covariance Vc² is estimated by the Kalman filter 120 as to how much the estimated value (DC component DCQ) can be trusted. As it is determined that the estimated value close to a true value is obtained, the error covariance Vc² decreases. In the present embodiment, as the error covariance Vc² decreases, a signal level for performing a stop command of observation update processing is reduced. Thereby, in a situation where the estimated value is converged to the true value (the error covariance Vc² is decreased), the stop command of the observation update processing is performed by inputting a slight rotation to the gyro sensor. Accordingly, as compared with the comparative example, the estimation error of the DC component DCQ hardly occurs, and accuracy or stability of the estimated value can be improved.

Here, the Kalman filter processing is processing of estimating an optimum state of a system using an observed value acquired from the past to the present by assuming that a noise (error) is included in a variable representing the observed value and the state of the system. In a case of the present embodiment, the observed value is the input signal PI, and the variable which is estimated is the DC component DCQ. In the Kalman filter processing, the state is estimated by repeating observation update (observation process) and time update (prediction process). The observation update is a process of updating Kalman gain, the estimated value, and the error covariance by using update results of the observed value and the time. The time update is a process of predicting the estimated value at the next time and the error covariance by using the results of the observation update.

For example, predetermined values estimated in advance are used as the observation noise σₘₑₐₛ and the system noise σ_{sys}. In this case, the observation noise σₘₑₐₛ and the system noise σ_{sys} (or their variances σₘₑₐₛ² and σ_{sys}²) are stored in, for example, a register, a memory, and the like, and the Kalman filter 120 reads the observation noise σₘₑₐₛ and the system noise σ_{sys} from the register and the memory. Alternatively, as will be described later in the second configuration example, the signal processing device 100 may include a noise estimation circuit 110 that dynamically changes the observation noise σₘₑₐₛ and the system noise σ_{sys}. In this case, the observation noise σₘₑₐₛ and the system noise σ_{sys} are supplied from the noise estimation circuit 110 to the Kalman filter 120.

The DC component DCQ estimated (extracted) by the Kalman filter 120 is a component whose frequency is lower than a desired signal component to be extracted from the input signal PI. For example, in a gyro sensor, the input signal PI (physical quantity signal) includes offset, and a change based on the offset is an actual signal component. A frequency of the signal component corresponds to a frequency of motion detected by the gyro sensor. Since the offset varies with time due to a temperature change or the like, the offset is not a frequency of zero, but has a frequency lower than the frequency of the motion.

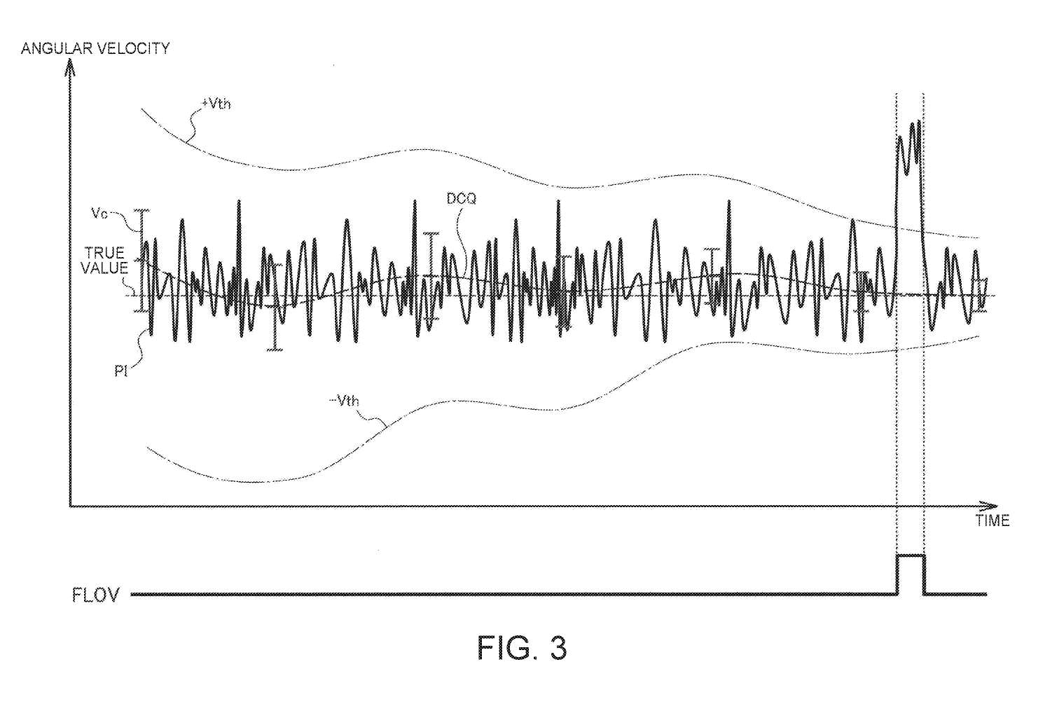

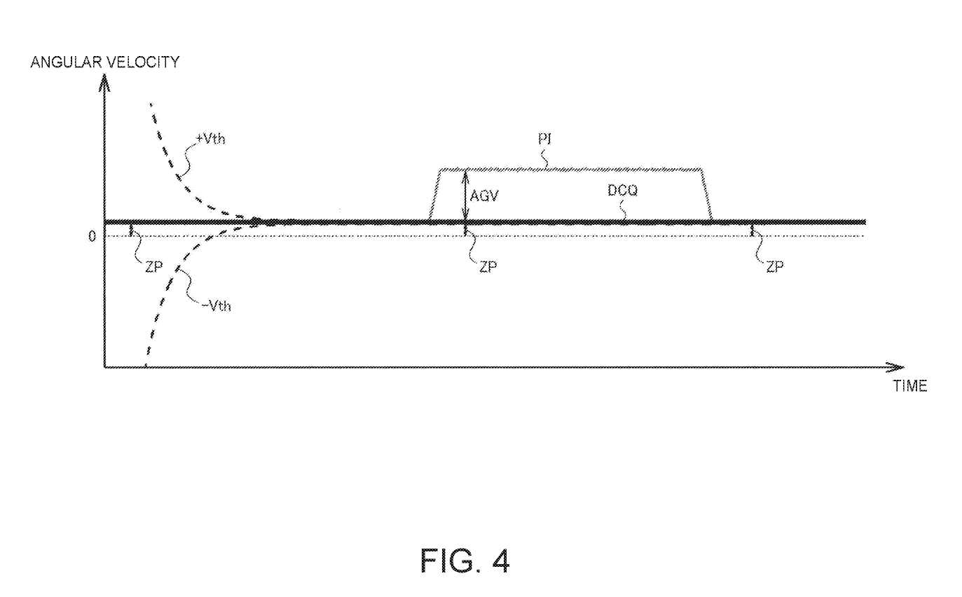

Hereinafter, an operation of the signal processing device 100 will be described with reference to FIGS. 3 and 4. FIG. 3 is a first timing chart schematically illustrating the operation of the signal processing device according to the present embodiment.

A noise is included in the input signal PI which is the observed value. The Kalman filter 120 estimates a true value (true zero point) from the input signal PI including the noise and outputs the estimated value as the DC component DCQ. In addition, the Kalman filter 120 estimates a probability of the estimated value as the error covariance Vc². FIG. 3 illustrates an error estimation value Vc (deviation) which is a square root of the error covariance. In addition, in FIG. 3, the error estimation value Vc is illustrated in a range, but an upper limit of the range corresponds to +Vc and a lower limit corresponds to −Vc. The Kalman filter 120 estimates that a true value exists in a distribution which is centered on the estimated value (DC component DCQ) and which uses the error estimation value Vc as a deviation.

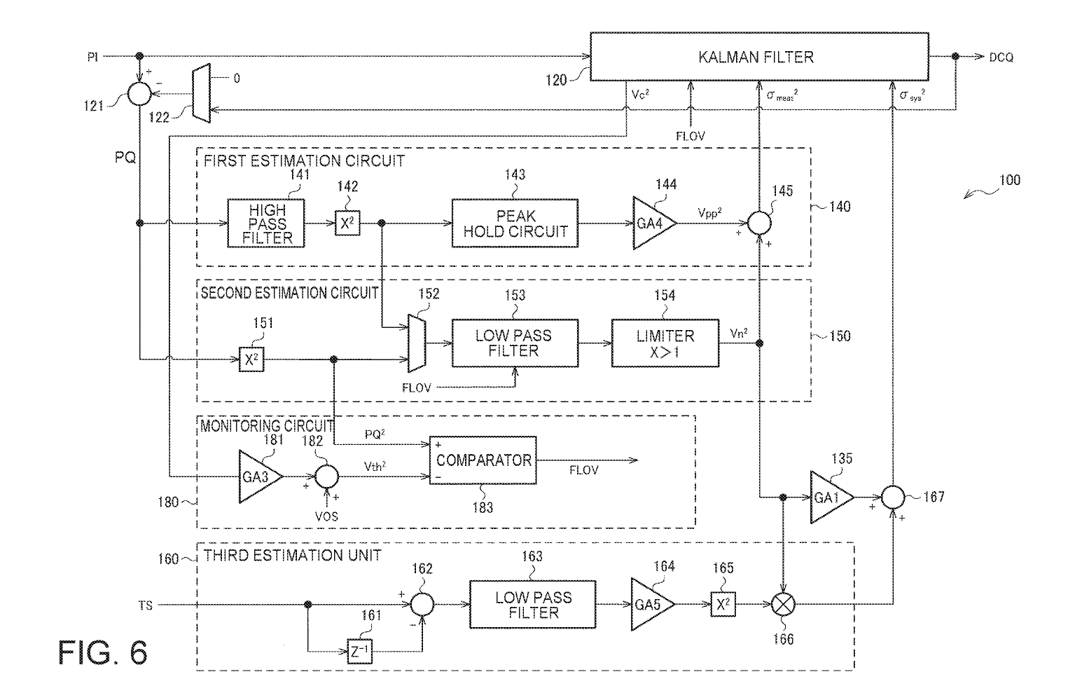

The monitoring circuit 180 sets the threshold value Vth according to the error estimation value Vc. Specifically, the smaller the error estimation value Vc is, the smaller the threshold value Vth is. For example, as will be described below with reference to FIG. 6, a square Vth² of the threshold value is obtained by a first-order function having the error covariance Vc² as a variable. In a case where the input signal PI is out of a range of −Vth to +Vth, the monitoring circuit 180 changes a stop flag FLOV from an inactive (first logic level, low level) state to an active (second logic level, high level) state. FIG. 3 illustrates an example in which the stop flag FLOV is active in a case where the input signal PI exceeds +Vth. Activating the stop flag FLOV corresponds to a stop command of the observation update processing, and the Kalman filter 120 stops the observation update processing while the stop flag FLOV is active.

FIG. 4 is a second timing chart illustrating an operation of the signal processing device according to the present embodiment.

As in the comparative example, it is assumed that the input signal PI includes DC offset corresponding to the angular velocity ZP. In a case where the input signal PI does not greatly change from the DC offset (gyro sensor is stationary), the error estimation value Vc decreases with lapse of time, and thereby, the threshold value Vth is converged to the vicinity of the DC offset (DCQ which is an estimated value thereof).

At this time, it is assumed that a very small rotation is input to the gyro sensor and the input signal becomes PI=AGV+ZP. If the threshold value Vth is sufficiently converged, |AGV+ZP|>Vth, and thereby, the stop flag FLOV becomes active and the observation update processing of the Kalman filter 120 is stopped. If a true value of the DC offset can be estimated by the Kalman filter 120 before the observation update processing is stopped, DCQ=ZP. While |AGV+ZP|>Vth, the estimated value DCQ does not change, and thereby, DCQ=ZP is maintained. The detection value of the angular velocity is PI−DCQ=(AGV+ZP)−ZP=AGV, and the correct angular velocity AGV is detected.

If the gyro sensor stops again, the input signal returns to PI=0+ZP and the observation update processing is resumed (stop of the observation update processing is canceled). Since the observation update processing is resumed in a state where DCQ=ZP is maintained, the detection value of the angular velocity becomes PI−DCQ=(0+ZP)−ZP=0, and the correct angular velocity is detected.

As described above, in the present embodiment, in a case where a signal level corresponding to the input signal PI exceeds the threshold value Vth based on the error covariance Vc², the monitoring circuit 180 performs the stop command of the observation update processing. Specifically, the threshold value Vth changes according to the error covariance Vc².

By doing so, it is possible to realize determination processing based on the error covariance Vc² by comparing a signal level corresponding to the input signal PI and the threshold value Vth based on the error covariance Vc². Since the threshold value Vth converges to the estimated value (DC component DCQ) as the error covariance Vc² converges, the observation update processing of the Kalman filter 120 can be stopped only by slight rotation of the gyro sensor. Meanwhile, in a case where the error estimation value Vc is large (for example, when the gyro sensor starts), the error covariance Vc² is large (a difference between the threshold value Vth and the DC component DCQ is large), and thereby, a possibility that the observation update processing is stopped is low. Accordingly, it is possible to converge the estimated value quickly to the vicinity of the true value.

The fact that the signal level corresponding to the input signal PI exceeds the threshold value Vth means that a signal corresponding to the input signal PI is out of a range from a negative threshold value (−Vth) to a positive threshold value (+Vth). That is, that fact means that the signal corresponding to the input signal PI exceeds the positive threshold value (+Vth) or falls below the negative threshold value (−Vth).

In addition, in the present embodiment, the stop command is a command to stop update of at least one of the estimated value (DC component DCQ) and the error covariance Vc².

The Kalman filter 120 updates the estimated value and the error covariance Vc² as the observation update processing. The monitoring circuit 180 commands update stop of the estimated value, update stop of the error covariance Vc², or update stop of the estimated value and the error covariance Vc². In each case, the Kalman filter 120 stops the update of the estimated value, the update of the error covariance Vc², and the update of the estimated value and the error covariance Vc².

By doing so, in a case where the signal level corresponding to the input signal PI exceeds the threshold value Vth, at least a part of the observation update performed by the Kalman filter 120 is stopped. In a case where the input signal PI that hinders an estimation of the DC offset (zero point) is input, at least a part of the observation update is stopped, and thereby, accuracy or stability of the estimated value can be improved. From a viewpoint of the accuracy or the stability of the estimated value, it is more desirable to stop updating at least the estimated value.

In addition, in the present embodiment, the monitoring circuit 180 may perform determination processing on a signal level of a signal obtained by subtracting the DC component DCQ from the input signal PI.

Since the input signal PI includes the DC offset, a signal level thereof includes a magnitude of the DC offset. In this regard, by subtracting the DC component DCQ from the input signal PI, a signal level (signal level estimated as a true signal level) from which the DC offset (estimated value) is removed is obtained. By comparing this signal level with the threshold value Vth, more accurate threshold value determination can be made.

The signal level used for the determination processing is not limited to the signal level of the signal obtained by subtracting the DC component DCQ from the input signal PI, and may be a signal level corresponding to the input signal PI. For example, the signal level of the input signal PI may be used as it is. Alternatively, some processing (addition, subtraction, multiplication, or the like) may be performed on the input signal PI, and a signal level of the processed signal may be used. For example, a signal obtained by performing high pass filtering of the input signal PI may be subtracted from the input signal PI, and a signal level of the subtracted signal may be used.

In addition, in the present embodiment, the monitoring circuit 180 may perform determination processing on a signal level of a signal obtained by squaring the signal corresponding to the input signal PI.

By squaring the signal, a signal level representing (the square of) a magnitude of the signal corresponding to the input signal PI can be generated. Thereby, a comparison between the signal level and the threshold value Vth becomes a comparison between positive values, and it can be determined whether or not the signal level exceeds the threshold value Vth.

The signal level used for the determination processing is not limited to the signal level of the signal obtained by squaring the signal corresponding to the input signal PI, and may be a value representing a magnitude of the signal value. A magnitude of the signal value is a positive value generated based on the signal and is, for example, an absolute value of the signal value, a square of the signal value, a peak-to-peak value of the signal, a difference between a maximum value and a minimum value of the signal within a predetermined time, and the like. Alternatively, it may be any value obtained by performing some calculation (such as gain processing) on those.

### 3. Second Configuration Example of Signal Processing Device

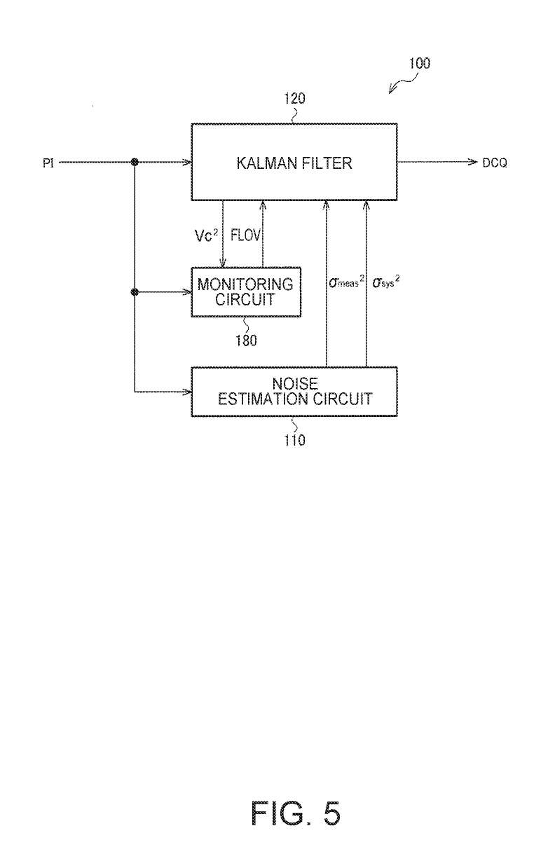

FIG. 5 is a second configuration example of a signal processing device according to the present embodiment. In FIG. 5, the signal processing device 100 further includes a noise estimation circuit 110. The same reference numerals or symbols are attached to the configuration elements described with reference to FIG. 2, and description thereof will be appropriately omitted. In addition, the present embodiment is not limited to the configuration of FIG. 5, and various modifications such as omitting apart of configuration elements and adding other configuration elements can be made.

The noise estimation circuit 110 estimates the observation noise σₘₑₐₛ and the system noise σ_{sys} that dynamically change according to the input signal PI (input data). Specifically, the noise estimation circuit 110 generates the observation noise variance σₘₑₐₛ² and the system noise variance σ_{sys}² from the input signal PI, and changes the observation noise variance σₘₑₐₛ² and the system noise variance σ_{sys}² according to the signal value of the input signal PI or a change thereof.

The Kalman filter 120 performs Kalman filter processing based on the observation noise variance a σₘₑₐₛ² and the system noise variance σ_{sys}² estimated by the noise estimation circuit 110, and extracts the DC component DCQ of the input signal PI.

In a general Kalman filter, an initial value of the error covariance and system noise are given in advance as known items. A value of the error covariance is updated by observation update and time update. As such, in the general Kalman filter, the observation noise and the system noise are not newly given from the outside during repetition of the update.

Meanwhile, in the present embodiment, the observation noise σₘₑₐₛ and the system noise σ_{sys} dynamically change and are supplied from the outside to the Kalman filter 120. The observation noise σₘₑₐₛ and the system noise σ_{sys} influence internal variables such as a Kalman gain g(k), as will be represented by following Formula (1) to Formula (5). That is, it means that a filter characteristic of the Kalman filter 120 can be adaptively controlled by controlling the observation noise σₘₑₐₛ and the system noise σ_{sys}. In the present embodiment, by using this, it is possible to set a passband to a low frequency when the DC component of the input signal PI (a physical quantity signal of the gyro sensor) does not change and to expand the passband of a signal component to the low frequency side. In addition, when the DC component changes, the observation noise σₘₑₐₛ and the system noise σ_{sys} are changed to widen the passband, thereby, following a change in the DC component. By doing so, it is possible to improve a transient response to the change of the input signal PI and followability to the change of the DC component.

Hereinafter, detailed Kalman filter processing will be described below. The Kalman filter 120 performs first-order linear Kalman filter processing indicated by following Formula (1) to Formula (5).

$$\begin{matrix}{x}^{-} ( k ) = x ( k - 1 ) & ( 1 ) \\ {P}^{-} ( k ) = P ( k - 1 ) + {{σ}_{sys} ( k - 1 )}^{2} & ( 2 ) \\ g ( k ) = \frac{{P}^{-} ( k )}{{P}^{-} ( k ) + {{σ}_{meas} ( k )}^{2}} & ( 3 ) \\ x ( k ) = {x}^{-} ( k ) + g ( k ) ( y ( k ) - {x}^{-} ( k ) ) & ( 4 ) \\ P ( k ) = ( 1 - g ( k ) ) {P}^{-} ( k ) & ( 5 )\end{matrix}$$

Formula (1) and Formula (2) are formulas of time update (prediction process), and Formula (3) to Formula (5) are formulas of observation update (observation process). k represents a discrete time, and the time update and the observation update are performed once each time k progresses by one. x(k) is an estimated value of the Kalman filter 120. That is, DCQ=x(k). x⁻(k) is a predictive estimated value predicted before the observed value is obtained. P(k) is an error covariance of the Kalman filter 120. That is, Vc²=P(k). P⁻(k) is an error covariance predicted before the observed value is obtained. y(k) is the observed value. That is, PI=y(k). σ_{sys}(k) is a system noise and a σₘₑₐₛ(k) is the observation noise.

The Kalman filter 120 stores an estimated value x(k−1) and an error covariance P(k−1) updated at a preceding time k−1. Then, the Kalman filter receives the observed value y(k), the observation noise σₘₑₐₛ (k) and the system noise σ_{sys} (k) at a current time k and performs time update and observation update of Formula (1) to Formula (5) by using the observed value y(k), the observation noise σₘₑₐₛ (k) and the system noise σ_{sys}(k), and outputs the estimated value x(k) as the DC component.

As described in the first configuration example, stop of the observation update processing is update stop of at least one of the estimated value and the error covariance. The update stop of the estimated value is to stop the update performed by Formula (4). For example, storing the calculation result on the right side of Formula (4) in the register corresponds to updating the estimated value. By stopping the storage in the register, the updating the estimated value may be stopped. Alternatively, updating the estimated value may be stopped by stopping the calculation on the right side of Formula (4). The stop updating the error covariance is to stop the update performed by Formula (5).

### 4. Detailed Configuration Example of Signal Processing Device

FIG. 6 is a detailed configuration example of the signal processing device according to the present embodiment. The signal processing device 100 includes the Kalman filter 120, a first estimation circuit 140, a second estimation circuit 150, a third estimation circuit 160, the monitoring circuit 180, a subtraction processing circuit 121, a selector 122, a gain processing circuit 135, and an addition processing circuit 167. The first estimation circuit 140, the second estimation circuit 150, the third estimation circuit 160, the gain processing circuit 135, and the addition processing circuit 167 correspond to the noise estimation circuit 110 in FIG. 5. The present embodiment is not limited to the configuration of FIG. 6, and various modifications such as omitting a part of configuration elements thereof and adding other configuration elements can be made.

The selector 122 selects either the DC component DCQ estimated by the Kalman filter 120 or data “0”. The subtraction processing circuit 121 subtracts an output of the selector 122 from the input signal PI and outputs the result as a signal PQ. In a case where the selector 122 selects the DC component DCQ, PQ=PI−DCQ, and in a case where the selector 122 selects data “0”, PQ=PI. The selector 122 may be omitted and the DC component DCQ may be directly input to the subtraction processing circuit 121. Alternatively, the selector 122 and the subtraction processing circuit 121 may be omitted, and the input signal PI may be directly used as the signal PQ.

The monitoring circuit 180 includes a gain processing circuit 181, an offset addition processing circuit 182, and a comparator 183. The gain processing circuit 181 performs gain processing of the error covariance Vc². The offset addition processing circuit 182 adds an offset VOS to an output of the gain processing circuit 181. The comparator 183 performs processing of comparing a signal level of the signal PQ with an output of the offset addition processing circuit 182 as determination processing based on the error covariance Vc².

Specifically, the gain processing circuit 181 multiplies the error covariance Vc² by a gain GA3. The output of the offset addition processing circuit 182 corresponds to a square (Vth²) of the threshold value Vth, and following Formula (6) is obtained. The comparator 183 compares a square (PQ²) of the signal PQ with the square (Vth²) of the threshold value Vth, outputs an active stop flag FLOV in a case where the square (PQ²) of the signal PQ is larger than the square (Vth²) of the threshold value Vth, and outputs an inactive stop flag FLOV in a case where the square (PQ²) of the signal PQ is smaller than the square (Vth²) of the threshold value Vth. Details of the gain GA3 and the offset VOS of in Formula (6) will be described below.

Vth²=GA3×Vc²+VOS (6)

According to the present embodiment, the threshold value Vth that changes according to the error covariance Vc² can be obtained by performing gain processing of the error covariance Vc² and adding the offset VOS to the gain processing result. Whether or not a signal level exceeds the threshold value Vth that changes according to the error covariance Vc² can be determined by comparing a signal level of the signal PQ with an output of the offset addition processing circuit 182. In addition, since a square of the threshold value Vth is obtained by a first-order function (gain processing, offset addition processing) of the error covariance Vc², the threshold value Vth can be adjusted by the first-order function. Thereby, the appropriate threshold value Vth can be set for the system.

The first estimation circuit 140 estimates a noise due to a motion (a large change in the input signal PI) of a gyro sensor. Specifically, the first estimation circuit 140 includes a high pass filter 141, a square calculation processing circuit 142, a peak hold circuit 143, a gain processing circuit 144, and an addition processing circuit 145.

The high pass filter 141 removes a DC component from the signal PQ. Since a square mean is performed in a rear stage, it is possible to prevent the DC component from being squared and becoming an error of the observation noise σₘₑₐₛ by removing the DC component. The square calculation processing circuit 142 squares a signal from the high pass filter 141. The peak hold circuit 143 receives the signal having an AC component passed through the high pass filter 141 and the square calculation processing circuit 142, and performs peak hold of the signal. The gain processing circuit 144 performs gain processing (processing of multiplying by a gain GA4) on an output of the peak hold circuit 143, and outputs the gain processing result as a motion noise Vpp² (variance of motion noise). The addition processing circuit 145 adds the motion noise Vpp² to a floor noise Vn² generated by the second estimation circuit 150, and outputs the addition result as the observation noise variance σₘₑₐₛ².

As the motion detected by the gyro sensor increases, a signal from the peak hold circuit 143 also increases, and thereby, as the motion increases, the observation noise σₘₑₐₛ increases. If the observation noise σₘₑₐₛ increases, the Kalman gain g(k) decreases as can be seen from Formula (3), and the estimated value x(k) can be calculated by lowering a weight of the observed value y(k) as can be seen from Formula (4). Thereby, as an AC component of the motion increases, influence of the observed value y(k) decreases, and DC components with higher accuracy can be extracted.

A floor noise output from the motion noise Vpp² is represented by following Formula (7). Vn is the floor noise of the input signal PI. GA4 is a gain of the gain processing circuit, and is a coefficient for adjusting a degree of influence of the peak hold circuit 143. Peak hold processing of the squared signal of noise results in outputting a maximum value during a certain period of time, and an effective gain Gₚₑₐₖ is applied to an average value of the squared signal of noise. The peak hold circuit 143 performs the peak hold of the input signal and then outputs a signal divided by Gₚₑₐₖ.

Vpp²=GA4×Vn² (7)

The second estimation circuit 150 estimates the floor noise of the input signal PI. Specifically, the second estimation circuit 150 includes a square calculation processing circuit 151, a selector 152, a low pass filter 153, and a limiter 154.

The square calculation processing circuit 151 squares the signal PQ. The selector 152 selects an output of the square calculation processing circuit 151 or an output of the square calculation processing circuit 142 of the first estimation circuit 140. The low pass filter 153 filters (smooths) a signal squared by the square calculation processing circuit 151 and obtains a root mean square. A noise component of the signal is extracted by the square mean. The limiter 154 performs a limit processing of a signal from the low pass filter 153. Specifically, in a case where the signal from the low pass filter 153 is lower than a lower limit value, the output is limited to the lower limit value, and in a case where the signal from the low pass filter 153 is larger than the lower limit value, the signal is output as it is. The lower limit value is smaller than an assumed minimum floor noise, and is, for example, one digit. As a result, the floor noise Vn² (variance of floor noise) is output from an output of the limiter 154.

The gain processing circuit 135 multiplies the floor noise Vn² from the second estimation circuit 150 by a constant gain GA1 and outputs the calculation result to the addition processing circuit 167. The gain GA1 is set as represented by following Formula (11). A derivation method of following Formula (11) will be described below.

First, a relationship between the observation noise σₘₑₐₛ and the system noise σ_{sys} in a state where sufficient time elapses is obtained. The state where sufficient time elapses may be assumed to be a situation of k=∞, and if a prior error covariance P⁻(k) converges to a constant value, following Formula (8) is satisfied. A converged value of the prior error covariance P⁻(k) is referred to as P₀.

P₀=P⁻(k)=P⁻(k+1) (8)

If the Kalman gain g(k) is solved by using a formula obtained by applying Formula (8) to Formula (2) and Formula (5) and a formula obtained by applying Formula (8) to Formula (3) as a simultaneous equation, Following Formula (9) is obtained. In following Formula (9), the Kalman gain g(k) in the convergence state k=∞ is set to g. In addition, it is assumed that σ_{sys}<<σₘₑₐₛ is satisfied because a passband is very low in the convergence state of the Kalman filter 120, on the right-hand side approximation.

$$g = g ( k = ∞ ) ≅ \frac{{σ}_{sys}}{{σ}_{meas}} \qquad ( 9 )$$

Since σ_{sys}²=g²σₘₑₐₛ² in the convergence state, the gain GA1=g² from Formula (9). If the relationship between a desired filter characteristic for extracting the DC component and the Kalman gain g is known, the gain GA1 can be set so as to obtain the desired filter characteristic.

A final propagation function when time elapses is obtained, a first-order conversion is applied to the propagation function, and a cutoff frequency f_{c} of a low pass filter characteristic included in the propagation function is obtained from Formula (1) and Formula (4), and if the Kalman gain g is solved, following Formula (10) is satisfied. fₛ is a sampling frequency (operation frequency) of the Kalman filter 120. In the approximation on the right side of following Formula (10), f_{c}<<fₛ is satisfied.

$$g = \frac{{σ}_{sys}}{{σ}_{meas}} ≅ \frac{2 π {f}_{c}}{{f}_{s}} \qquad ( 10 )$$

The gain GA1=g² can be obtained from the above equation (10), as represented by following Formula (11). In following Formula (11), a desired cutoff frequency (target cutoff frequency) to be finally obtained in a convergence state is set to f_{c}.

$$GA 1 = {( \frac{2 π {f}_{c}}{{f}_{s}} )}^{2} \qquad ( 11 )$$

The third estimation circuit 160 estimates variation of the zero point (DC offset) due to temperature variation. The third estimation circuit 160 increases the system noise σ_{sys} in a case where there is a temperature change, and returns the Kalman filter 120 from a convergence state to an estimation state. Specifically, the third estimation circuit 160 includes a delay circuit 161, a subtraction processing circuit 162, a low pass filter 163, a gain processing circuit 164, a square calculation processing circuit 165, a multiplication processing circuit 166, and an addition processing circuit 167.

The delay circuit 161 and the subtraction processing circuit 162 obtain a difference between a detection signal TS at time k of a temperature sensor and a detection signal TS at the preceding time k−1. The low pass filter 163 smooths the difference.

The gain processing circuit 164 multiplies a signal from the low pass filter 163 by a gain GA5. The square calculation processing circuit 165 squares the multiplied signal. The multiplication processing circuit 166 multiplies the squared signal by the floor noise Vn² from the second estimation circuit 150. The addition processing circuit 167 adds an output of the multiplication processing circuit 166 to an output of the gain processing circuit 135, and outputs the addition result to the Kalman filter 120 as the system noise variance σ_{sys}².

The gain GA 5 is set by following formula (12). TSEN is sensitivity (digi/° C.) of a temperature sensor, TCOEFF is a temperature coefficient (dps/° C.) of a gyro sensor, and SEN is sensitivity (digit/dps) of the gyro sensor.

$$GA 5 = \frac{SEN \times TCOEFF}{TSEN} \qquad ( 12 )$$

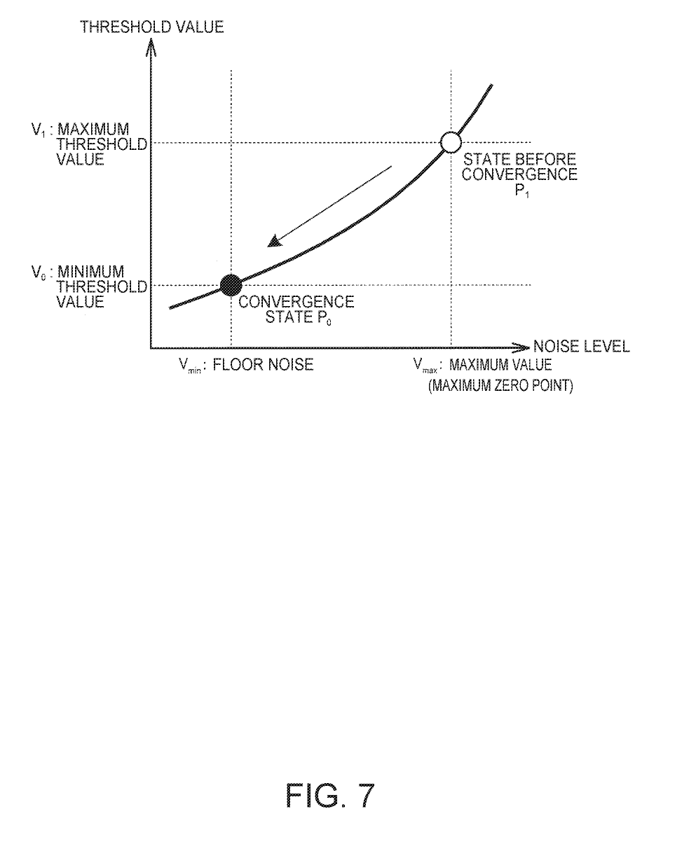

Hereinafter, the gain GA3 and the offset VOS of Formula (6) in which the monitoring circuit 180 sets the threshold value Vth will be described with reference to FIG. 7. FIG. 7 is a diagram illustrating a setting method of the threshold value Vth.

The observation noise variance a σₘₑₐₛ² is given by following Formula (13) from Formula (7).

σₘₑₐₛ²=Vpp²+Vn²=(1+GA4)×Vn² (13)

If a noise level of the input signal PI in a convergence state of the error covariance is referred to as Vₘᵢₙ (floor noise), Vn²=Vₘᵢₙ². At this time, following Formula (14) is satisfied from formula (13). In addition, when an operation starts (a state before convergence), the signal PQ becomes the DC component DCQ of the input signal PI. If a maximum value of the DC component DCQ is referred to as Vₘₐₓ (maximum zero point error), an output of the high pass filter 141 is Vₘₐₓ, an output of the square calculation processing circuit 142 is Vₘₐₓ², and an output of the gain processing circuit 144 is GA4×Vₘₐₓ². Meanwhile, an output of the low pass filter 153 becomes Vₘₐₓ², and following Formula (15) is satisfied. For the sake of simple calculation, an effective gain Gₚₑₐₖ of a peak hold circuit is set to 1.

σₘₑₐₛ²=(1+GA4)×Vₘᵢₙ² (14)

σₘₑₐₛ²=(1+GA4)×Vₘₐₓ² (15)

In a convergence state, following Formula (16) is satisfied from Formula (2), Formula (5), and Formula (9).

$$P ( k ) = ( 1 - g ( k ) ) ( P ( k - 1 ) + {σ}_{sys}^{2} ) \text{∼} \frac{1}{1 + \frac{{σ}_{sys}}{{σ}_{meas}}} ( P ( k - 1 ) + {σ}_{sys}^{2} ) \qquad ( 16 )$$

Following Formula (17) is obtained from Formula (8), Formula (10) and Formula (16) as the error covariance P₀ in the convergence state.

$${P}_{0} = \frac{2 π {f}_{c}}{{f}_{s}} {σ}_{meas}^{2} \qquad ( 17 )$$

If a state before convergence is a state before the time constant time of the target cutoff frequency f_{c}, following Formula (18) is obtained as an error covariance P₁ in a state before convergence.

$${P}_{1} = β \times {P}_{0} , β = {( \frac{2 π {f}_{c}}{{f}_{s}} )}^{\frac{fs}{fc}} \qquad ( 18 )$$

As illustrated in FIG. 7, a threshold value in a state before convergence is set as a maximum threshold value V₁, and a threshold value in the convergence state is set as a minimum threshold value V₀. From Formula (6), the maximum threshold value V₁ can be obtained by following Formula (19) and the minimum threshold value V₀ can be obtained by following Formula (20).

V₁²=P₁×GA3+VOS (19)

V₀²=P₀×GA3+VOS (20)

If Formula (19) and Formula (20) are solved by using Formula (14), Formula (15), Formula (17), and Formula (18) as simultaneous equations, following Formula (21) and Formula (22) are obtained. That is, the gain GA3 of the monitoring circuit 180 is set by following Formula (21), and the offset VOS is set by following Formula (22).

$$GA 3 = \frac{{f}_{s}}{2 π {f}_{c} {G}_{0}^{2} ( {G}_{Hold}^{2} + 1 )} \times \frac{{V}_{1}^{2} - {V}_{0}^{2}}{β {V}_{max}^{2} - {V}_{min}^{2}} \qquad ( 21 )$$

### 5. Detection Device, Physical Quantity Measurement Device

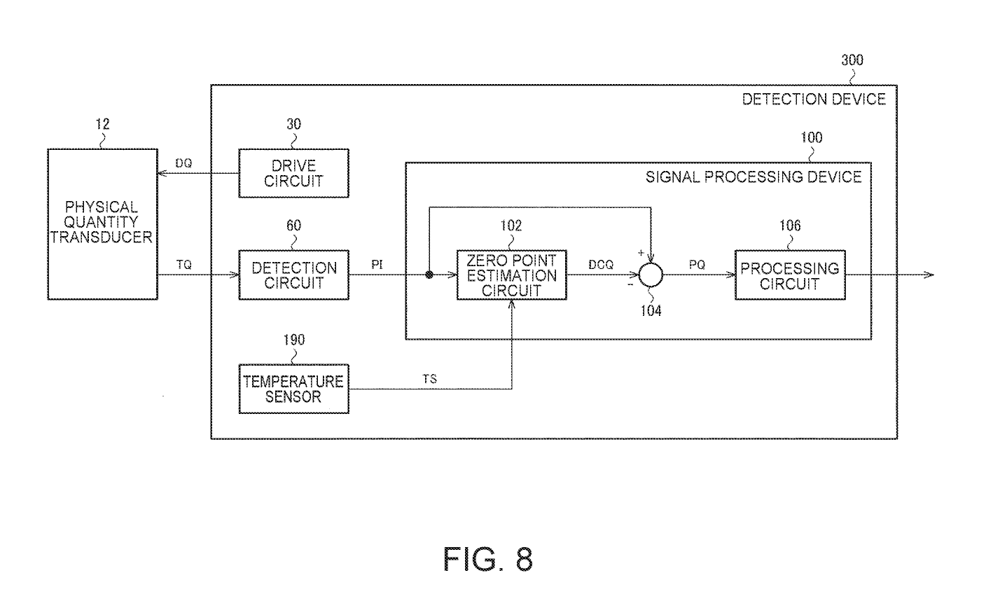

FIG. 8 illustrates a configuration example of a detection device including a signal processing device according to the present embodiment. The detection device 300 (circuit device, integrated circuit device) includes a drive circuit 30, a detection circuit 60, a signal processing device 100 (signal processing circuit), and a temperature sensor 190. The present embodiment is not limited to the configuration of FIG. 8, and various modifications such as omitting a part (for example, a temperature sensor) of configuration elements thereof and adding other configuration elements can be made.

The drive circuit 30 supplies a drive signal DQ to a physical quantity transducer 12 and drives the physical quantity transducer 12. The detection circuit 60 receives a detection signal TQ from the physical quantity transducer 12 and detects a physical quantity signal corresponding to a physical quantity. The signal processing device 100 extracts the DC component DCQ by using the physical quantity signal as the input signal PI.

Specifically, the physical quantity transducer 12 is an element or a device that detects a physical quantity. The physical quantity is, for example, angular velocity, angular acceleration, velocity, acceleration, distance, pressure, sound pressure, magnetic amount or time, and the like. The detection device 300 may detect the physical quantity, based on detection signals from a plurality of physical quantity transducers. For example, the first to third physical quantity transducers detect physical quantities of a first axis, a second axis, and a third axis, respectively. The physical quantities of the first axis, the second axis, and the third axis are, for example, angular velocities or angular accelerations around the first axis, the second axis, and the third axis, or are velocities or accelerations in directions of the first axis, the second axis, and the third axis. The first axis, the second axis, and the third axis are, for example, the X axis, the Y axis, and the Z axis, respectively. Only the physical quantities of two axes among the first axis to the third axis may be detected.

The signal processing device 100 includes a zero point estimation circuit 102, a subtraction processing circuit 104, and a processing circuit 106. For example, the signal processing device 100 is realized by a processor such as a digital signal processor (DSP), and, for example, processing of each circuit is realized by time division processing performed by the DSP. Alternatively, each circuit of the signal processing device 100 may be configured as individual hardware (logic circuit).

The zero point estimation circuit 102 dynamically changes an observation noise and a system noise, based on the input signal PI and the detection signal TS (temperature detection voltage) from the temperature sensor 190, and performs Kalman filter processing, based on the observation noise and the system noise to estimate the DC component DCQ (DC offset, zero point) of the input signal PI. The zero point estimation circuit 102 corresponds to the Kalman filter 120 and the monitoring circuit 180 in FIG. 2, or the Kalman filter 120, the monitoring circuit 180, and the noise estimation circuit 110 in FIG. 5.

The subtraction processing circuit 104 subtracts the DC component DCQ from the input signal PI and outputs the subtraction result as the signal PQ. The subtraction processing circuit 121 in FIG. 6 may be used as the subtraction processing circuit 104.

The processing circuit 106 performs various types of digital signal processing (for example, correction, integration, and the like) for the signal PQ and outputs a digital value representing a physical quantity. The type of the physical quantity output by the processing circuit 106 may be the same as or different from the type of the physical quantity detected by the detection circuit 60. For example, in the gyro sensor, the detection circuit 60 detects angular velocity but the processing circuit 106 may output the angular velocity or may output an angle obtained by integrating the angular velocity.

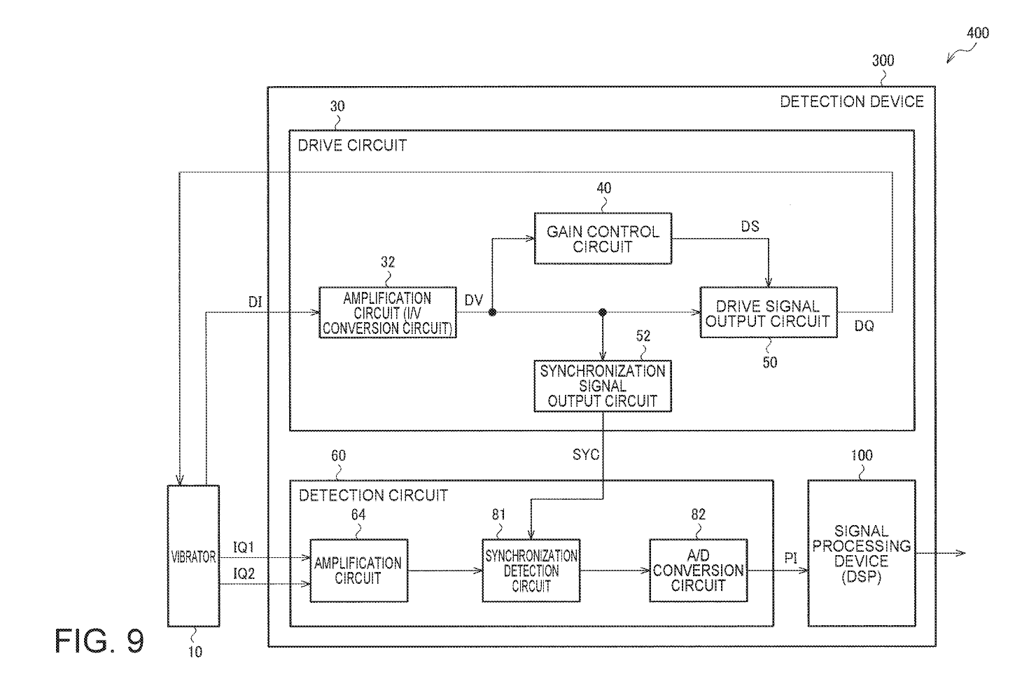

FIG. 9 is a configuration example of a physical quantity measurement device including the detection device (signal processing device) according to the present embodiment. FIG. 9 illustrates a configuration example of a gyro sensor that detects angular velocity as an example of the physical quantity measurement device. As described with reference to FIG. 7, the signal processing device 100 according to the present embodiment can be applied to the physical quantity measurement device that detects various physical quantities such as angular velocity, angular acceleration, velocity, acceleration, a distance, a pressure, a sound pressure, a magnetic amount, and time.

The gyro sensor 400 (angular velocity sensor) includes a vibrator 10, the drive circuit 30, the detection circuit 60, and the signal processing device 100.

The vibrator 10 (angular velocity detection element) is an element (physical quantity transducer) that detects Coriolis force acting on the vibrator 10 by rotation on a predetermined axis and outputs a signal corresponding to the Coriolis force. The vibrator 10 is, for example, a piezoelectric vibrator. The vibrator 10 is, for example, a quartz crystal vibrator or the like of a double T-shape, a T-shape, a tuning fork type, or the like. A micro electro mechanical systems (MEMS) vibrator or the like as a silicon vibrator formed by using a silicon substrate may be adopted as the vibrator 10.

The drive circuit 30 includes an amplification circuit 32 to which a feedback signal DI from the vibrator 10 is input, a gain control circuit 40 that performs an automatic gain control, and a drive signal output circuit 50 that outputs a drive signal DQ to the vibrator 10. In addition, the drive circuit 30 includes a synchronization signal output circuit 52 that outputs a synchronization signal SYC to the detection circuit 60.

The amplification circuit 32 (I/V conversion circuit) amplifies a feedback signal DI from the vibrator 10. For example, the amplification circuit converts the signal DI of a current from the vibrator 10 into a signal DV of a voltage and outputs the signal DV. The amplification circuit 32 can be realized by an operational amplifier, a feedback resistance element, a feedback capacitor, and the like.

The drive signal output circuit 50 outputs the drive signal DQ, based on the signal DV amplified by the amplification circuit 32. For example, in a case where the drive signal output circuit 50 outputs a drive signal of a rectangular wave (or a sine wave), the drive signal output circuit 50 can be realized by a comparator or the like.

The gain control circuit 40 (AGC) outputs a control voltage DS to the drive signal output circuit 50 to control an amplitude of the drive signal DQ. Specifically, the gain control circuit 40 monitors the signal DV and controls a gain of an oscillation loop. For example, the drive circuit 30 requires to keep the amplitude of a drive voltage supplied to the drive vibration unit of the vibrator 10 constant, in order to keep sensitivity of a gyro sensor constant. Accordingly, the gain control circuit 40 for automatically adjusting a gain is provided in an oscillation loop of a drive vibration system. The gain control circuit 40 variably and automatically adjusts the gain such that an amplitude (vibration speed of the drive vibration unit of the vibrator 10) of the feedback signal DI from the vibrator 10 is constant. The gain control circuit 40 can be realized by a full-wave rectifier that performs full-wave rectification of the output signal DV of the amplification circuit 32, an integrator that performs integration processing of an output signal of the full-wave rectifier, and the like.

The synchronization signal output circuit 52 receives the signal DV amplified by the amplification circuit and outputs the synchronization signal SYC (reference signal) to the detection circuit 60. The synchronization signal output circuit 52 can be realized by a comparator that performs binarization processing of the signal DV of a sine wave (alternating current) to generate the synchronization signal SYC of a rectangular wave, a phase adjustment circuit (phase shifting circuit) that adjusts a phase adjustment of the synchronization signal SYC, and the like.

The detection circuit 60 includes an amplification circuit 64, a synchronization detection circuit 81, an A/D conversion circuit 82, and the signal processing device 100 (DSP). The amplification circuit 64 receives first and second detection signals IQ1 and IQ2 from the vibrator 10, and performs electric charge-voltage conversion, differential signal amplification, gain adjustment, and the like. The synchronization detection circuit 81 performs a synchronization detection, based on the synchronization signal SYC from the drive circuit 30. The A/D conversion circuit 82 performs A/D conversion of a signal in which synchronization detection is completed. The signal processing device 100 performs digital filter processing and digital correction processing (for example, zero point correction processing, sensitivity correction processing, and the like) for a digital signal (input signal PI) from the A/D conversion circuit 82. The zero point correction processing is processing of estimating the zero point by the Kalman filter processing and correcting the zero point of the input signal PI.

### 6. Vehicle and Electronic Apparatus

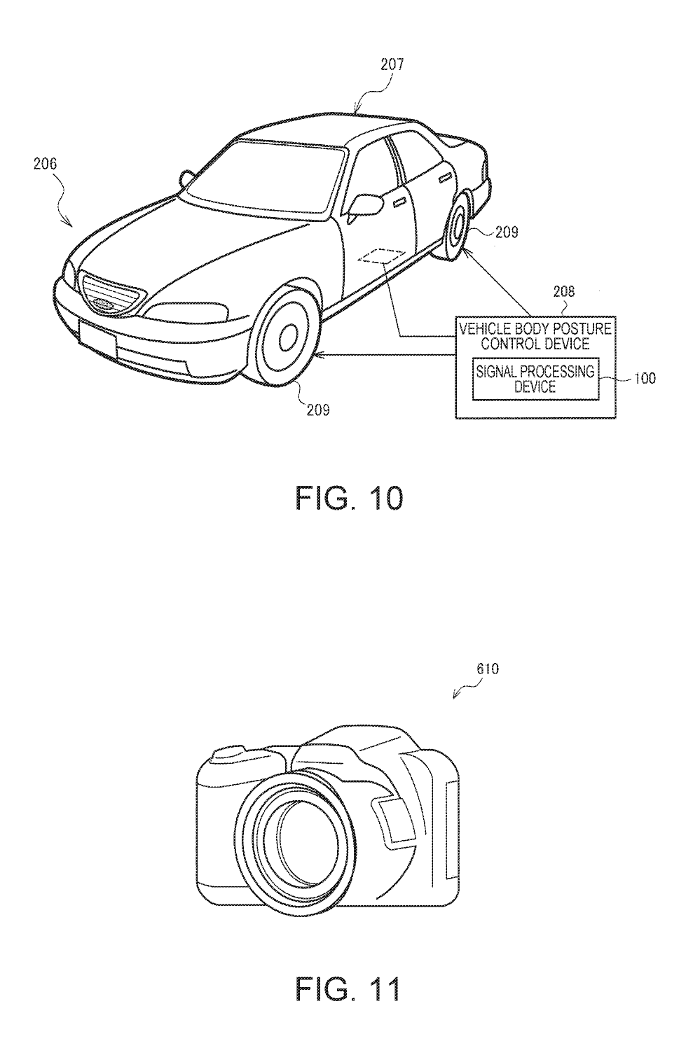

FIG. 10 and FIG. 11 are examples of a vehicle and an electronic apparatus including the signal processing device according to the present embodiment. The signal processing device 100 according to the present embodiment can be incorporated into various vehicles such as a car, an airplane, a motorcycle, a bicycle, a ship, and the like. The vehicle is an apparatus or a device that includes a drive mechanism such as an engine or a motor, a steering mechanism such as a steering wheel or a rudder, and various kinds of electronic apparatuses, and moves on the ground, the sky, or the sea.

FIG. 10 schematically illustrates an automobile 206 as a specific example of the vehicle. A gyro sensor (not illustrated) including the signal processing device 100 is incorporated in the automobile 206. The gyro sensor can detect a posture of a vehicle body 207. A detection signal of the gyro sensor is supplied to a vehicle body posture control device 208. For example, the vehicle body posture control device 208 can control hardness of a suspension in accordance with a posture of the vehicle body 207 or can control brakes of individual wheels 209. In addition, the posture control can be used in various vehicles such as a bipedal walking robot, an aircraft, and a helicopter. A gyro sensor can be incorporated to realize the posture control.

FIG. 11 schematically illustrates a digital still camera 610 as a specific example of an electronic apparatus. For example, the digital still camera 610 can perform camera shake correction by using the gyro sensor and the acceleration sensor. In addition, a biological information detection device (wearable health device such as a pulse rate meter, a pedometer, an activity meter, and the like) can be used as a specific example of the electronic apparatus. The biological information detection device can detect a body motion of a user or can detect a motion state by using the gyro sensor and the acceleration sensor. As such, the signal processing device 100 according to the present embodiment can be applied to various electronic apparatuses such as the digital still camera 610 and the biological information detection device.

In addition, a robot can be used as a specific example of a vehicle or an electronic apparatus. The signal processing device 100 according to the present embodiment can be applied to, for example, a movable portion (arm, joint) and a main body portion of a robot. The robot can be used for any of a vehicle (travel and walking robot) and an electronic apparatus (non-travel and non-walking robot). In a case of the travel and walking robot, for example, a gyro sensor (including the signal processing device according to the present embodiment) can be used for an autonomous travel.

Although the present embodiments are described in detail as above, it will be easily understood by those skilled in the art that various modifications can be made without practically departing from novel matters and effects of the invention. Thus, all the modifications are included in the scope of the invention. For example, in the specification or drawings, a term described at least once together with a different term that is broader or equivalent can be replaced with a different term at any point of the specification or the drawings. In addition, all combinations of the present embodiments and modification examples are also included in the scope of the invention. In addition, the configurations and operation of the signal processing device, the detection device, the physical quantity measurement device, the electronic apparatus, and the vehicle are not limited to those described in the present embodiments, and various modifications can be made.

The entire disclosure of Japanese Patent Application No. 2017-062057, filed Mar. 28, 2017 is expressly incorporated by reference herein.

What is claimed is:

1. A signal processing device comprising:
a Kalman filter configured to perform Kalman filter processing based on an observation noise and a system noise and output a DC component of an input signal as an estimated value; and
a monitoring circuit,
wherein the Kalman filter outputs an error covariance of the estimated value, and
wherein the monitoring circuit performs a stop command of observation update processing in the Kalman filter, with respect to a signal level corresponding to the input signal, based on a result of determination processing based on the error covariance.

2. The signal processing device according to claim 1, wherein the monitoring circuit performs the stop command in a case where the signal level exceeds a threshold value based on the error covariance.

3. The signal processing device according to claim 1, wherein the stop command is a command of update stop of at least one of the estimated value and the error covariance.

4. The signal processing device according to claim 1, wherein the monitoring circuit performs the determination processing with respect to the signal level of a signal which is obtained by subtracting the estimated value from the input signal.

5. The signal processing device according to claim 1, wherein the monitoring circuit performs the determination processing with respect to the signal level of a signal which is obtained by performing square calculation processing of a signal corresponding to the input signal.

6. The signal processing device according to claim 1, wherein the monitoring circuit includes a gain processing circuit configured to perform gain processing of the error covariance, an offset addition processing circuit configured to perform offset addition processing to an output of the gain processing circuit, and a comparator configured to perform processing of comparing the signal level with an output of the offset addition processing circuit as the determination processing.

7. The signal processing device according to claim 1, further comprising:
a noise estimation circuit configured to estimate the observation noise and the system noise which dynamically change according to the input signal.

8. A detection device comprising:
a drive circuit configured to drive a physical quantity transducer;
a detection circuit configured to receive a detection signal from the physical quantity transducer and detect a physical quantity signal corresponding to a physical quantity; and
the signal processing device according to claim 1, which extracts the DC component that is the estimated value by using the physical quantity signal as the input signal.

9. A detection device comprising:
a drive circuit configured to drive a physical quantity transducer;
a detection circuit configured to receive a detection signal from the physical quantity transducer and detect a physical quantity signal corresponding to a physical quantity; and
the signal processing device according to claim 2, which extracts the DC component that is the estimated value by using the physical quantity signal as the input signal.

10. A detection device comprising:
a drive circuit configured to drive a physical quantity transducer;
a detection circuit configured to receive a detection signal from the physical quantity transducer and detect a physical quantity signal corresponding to a physical quantity; and
the signal processing device according to claim 3, which extracts the DC component that is the estimated value by using the physical quantity signal as the input signal.

11. A detection device comprising:
a drive circuit configured to drive a physical quantity transducer;
a detection circuit configured to receive a detection signal from the physical quantity transducer and detect a physical quantity signal corresponding to a physical quantity; and
the signal processing device according to claim 4, which extracts the DC component that is the estimated value by using the physical quantity signal as the input signal.

12. A physical quantity measurement device comprising:
the detection device according to claim 8; and
the physical quantity transducer.

13. An electronic apparatus comprising:
the signal processing device according to claim 1.

14. An electronic apparatus comprising:
the signal processing device according to claim 2.

15. An electronic apparatus comprising:
the signal processing device according to claim 3.

16. An electronic apparatus comprising:
the signal processing device according to claim 4.

17. A vehicle comprising:
the signal processing device according to claim 1.

18. A vehicle comprising:
the signal processing device according to claim 2.

19. A vehicle comprising:
the signal processing device according to claim 3.

20. A vehicle comprising:
the signal processing device according to claim 4.
